(19) United States
(12) Patent Application Publication
(10) Pub. No.: US 2026/0173871 A1
(43) Pub. Date: Jun. 18, 2026

(54) SEMICONDUCTOR DEVICE

(71) Applicant: RENESAS ELECTRONICS CORPORATION, Tokyo (JP)

(72) Inventor: Norikazu MOTOHASHI, Tokyo (JP)

(21) Appl. No.: 19/421,293

(22) Filed: Dec. 16, 2025

(30) Foreign Application Priority Data
Dec. 17, 2024 (JP) 2024-220838

(51) Int. Cl. H10W 40/20; H10B 80/00; H10D 80/30; H10W 40/22; H10W 70/60; H10W 90/00; H10W 90/10

(52) U.S. Cl. CPC H10W 40/242; H10W 40/226; H10W 40/233; H10W 90/10; H10W 90/736; H10B 80/00; H10D 80/30; H10W 70/611

(57) ABSTRACT

A semiconductor device includes: a first semiconductor component mounted on a wiring substrate; a second semiconductor component mounted on the wiring substrate; and a lid. A height of a first upper surface of the first semiconductor component is lower than a height of a second upper surface of the second semiconductor component. A cover portion of the lid includes a portion that forms a shape protruding in a direction toward the first semiconductor component at a position facing the first semiconductor component. A third upper surface of the cover portion includes: a bottom surface that is a part of the portion; a fourth upper surface arranged at a position which is higher than the bottom surface; and a side surface connecting the bottom surface and the fourth upper surface.

### CROSS-REFERENCE TO RELATED APPLICATIONS

The disclosure of Japanese Patent Application No. 2024-220838 filed on Dec. 17, 2024, including the specification, drawings and abstract is incorporated herein by reference in its entirety.

### BACKGROUND

The present invention relates to a semiconductor device.

There are disclosed techniques listed below.
[Patent Document 1] Japanese Unexamined Patent Application Publication No. 2022-81872
[Patent Document 2] Japanese Unexamined Patent Application Publication No. 2017-112241

There is a semiconductor device including a lid covering a plurality of semiconductor components mounted on a wiring substrate (see, for example, Patent Document 1). Also, there is a structure where a semiconductor chip, which is covered by a lid, and a semiconductor package, which is exposed from the lid, are mounted on a wiring substrate (see, for example, Patent Document 2).

### SUMMARY

The lid mounted so as to cover the semiconductor component functions as a heat dissipation path to release the heat generated by the semiconductor component to the outside. However, it is found that there is a room for improvement in a structure where one lid is arranged so as to cover a plurality of semiconductor components. For example, due to the height difference among the plurality of semiconductor components, the heat dissipation characteristics of one semiconductor component may deteriorate.

Other objects and novel features will become apparent from the description of this specification and the accompanying drawings.

A semiconductor device according to one embodiment includes: a first semiconductor component mounted on a wiring substrate; and a second semiconductor component mounted on the wiring substrate. The semiconductor device includes: a metal plate; a first adhesive layer arranged between the first semiconductor component and the metal plate; and a second adhesive layer arranged between the second semiconductor component and the metal plate. The height of the upper surface of the first semiconductor component is lower than the height of the upper surface of the second semiconductor component. The metal plate includes: a flange portion adhered to the wiring substrate; and a cover portion located above the first semiconductor component and the second semiconductor component. The cover portion of the metal plate includes a first portion that forms a shape protruding in the direction toward the first semiconductor component at a position facing the first semiconductor component in cross-sectional view. The upper surface of the cover portion includes: a bottom surface that is a part of the first portion; an upper surface arranged at a position which is higher than the bottom surface; and a side surface connecting the bottom surface and the upper surface.

According to this embodiment, the performance of the semiconductor device can be improved.

### BRIEF DESCRIPTION OF THE DRAWINGS

FIG. 1 is a plan view of the mounting surface of a semiconductor device according to one embodiment.

FIG. 2 is a plan view showing the semiconductor device with the lid removed as shown in FIG. 1.

FIG. 3 is a cross-sectional view along line A-A of FIG. 1.

FIG. 4 is a cross-sectional view showing a state where a heat dissipation fin is mounted on the lid shown in FIG. 3.

FIG. 5 is an enlarged plan view showing the periphery of the portion protruding toward the semiconductor component of the lid shown in FIG. 1.

FIG. 6 is an enlarged cross-sectional view along line B-B of FIG. 5.

FIG. 7 is a plan view of a semiconductor device as a modified example of FIG. 1.

FIG. 8 is an enlarged plan view of the periphery of the recess shown in FIG. 7.

FIG. 9 is a cross-sectional view showing a state where a heat dissipation fin is mounted on the lid of the semiconductor device shown in FIG. 7.

FIG. 10 is a cross-sectional view showing another modified example of FIG. 4.

### DETAILED DESCRIPTION

### Description of Format, Basic Term, and Usage in This Application

In this application, the description of the embodiments is divided into multiple sections for convenience. These are not mutually independent and separate; one may be a detailed part of the other, or one may be a modified example of the other. In principle, repetitive descriptions of similar parts are omitted. Furthermore, each component in the embodiments is not essential unless it is clearly indicated as an essential component, limited in number theoretically, or obviously essential from the context.

Similarly, in the description of embodiments, materials, compositions, etc., even if stated as “X consisting of A”, unless clearly limited or obviously limited from the context, elements other than A are not excluded. For example, regarding components, it means “X containing A as the main component”. For instance, even if stated as “silicon member”, it is not limited to pure silicon but includes SiGe (silicon-germanium) alloys and other multi-component alloys with silicon as the main component, as well as other additives. Moreover, even if stated as gold plating, Cu layer, nickel plating, etc., unless otherwise specifically indicated, it includes members with gold, Cu, nickel, etc., as the main component, not just pure ones.

Furthermore, when specific numbers or quantities are mentioned, unless clearly limited or obviously limited from the context, those specific numbers are described as examples.

In the drawings of the embodiments, the same or similar parts are denoted by the same or similar symbols or reference numbers, and the description is not repeated in principle.

In the attached drawings, hatching and the like may be omitted even in a cross-section view when it becomes complicated or when it is clearly distinguished from a gap. In this connection, even if the hole is closed in plan, the outline of the background may be omitted when it is obvious from the description or the like. Furthermore, even if not in cross-sectional view, hatching or dot patterns may be applied to clearly indicate that it is not a gap or to clearly indicate the boundary of a region.

### Semiconductor Device

First, the semiconductor device of this embodiment will be described. In the following description, a semiconductor chip is a structure having a semiconductor substrate and multiple terminals (electrodes) formed on the semiconductor substrate. A semiconductor package is a structure in which one or more semiconductor chips are sealed by a sealing body. The semiconductor package has multiple terminals (electrodes) on at least one of the upper or lower surfaces. The semiconductor component is a general term for the semiconductor chip and semiconductor package described above. A semiconductor device is a structure having one or more semiconductor components and a wiring substrate on which the semiconductor components are mounted.

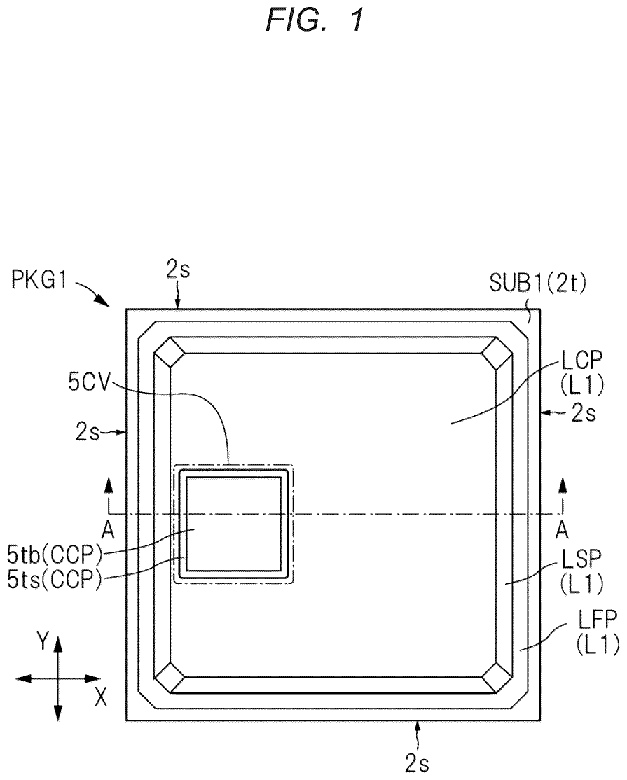

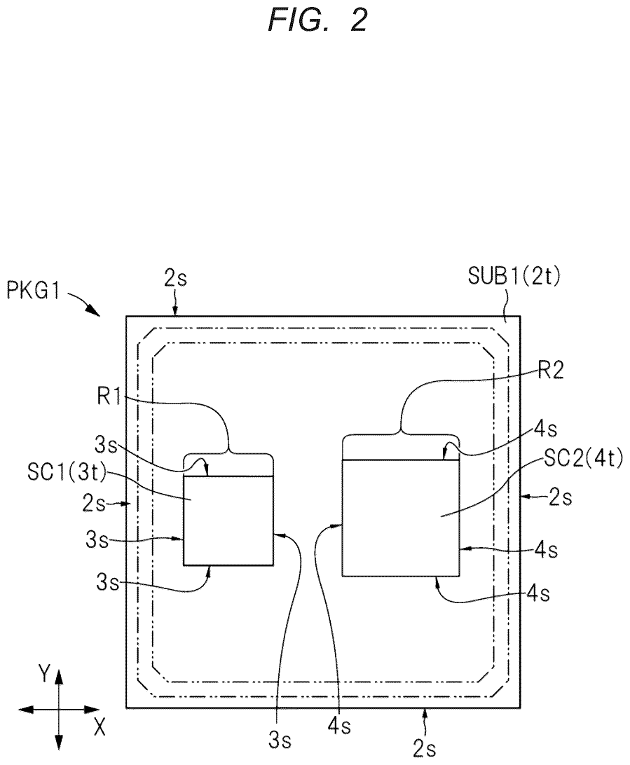

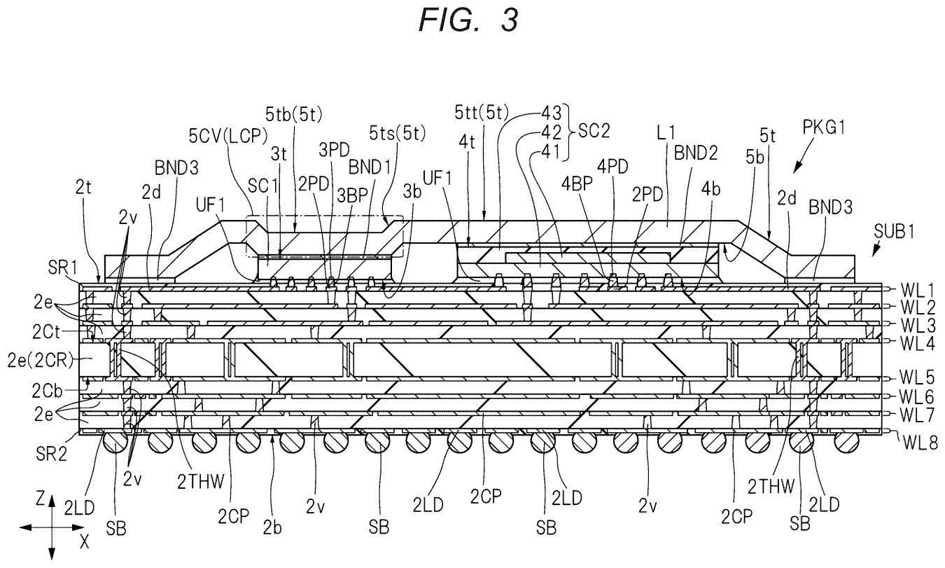

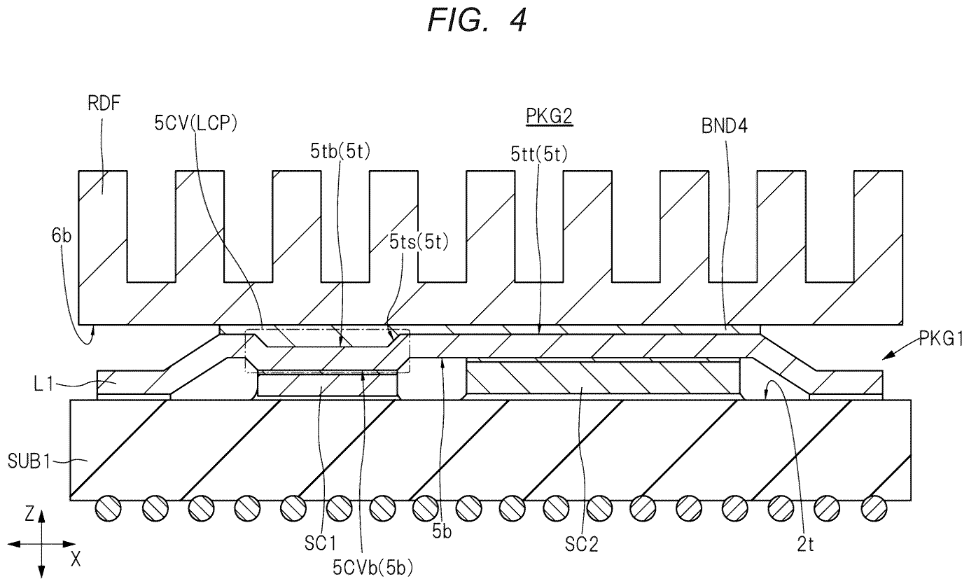

FIG. 1 is a plan view of the semiconductor device of this embodiment. FIG. 2 is a plan view showing the semiconductor device with the lid removed as shown in FIG. 1. FIG. 3 is a cross-sectional view along line A-A of FIG. 1. FIG. 4 is a cross-sectional view showing a state where a heat dissipation fin is mounted on the lid shown in FIG. 3.

In FIGS. 1 to 4, either the X direction (see FIGS. 1 to 4), the Y direction (see FIGS. 1 and 2), or the Z direction (see FIGS. 3 and 4) are described. The Y direction is the direction intersecting the X direction, and in the following description, the X and Y directions are orthogonal to each other. The Z direction is the direction orthogonal to each of the X and Y directions. In other words, the Z direction is the normal direction (in other words, the vertical direction) to the X-Y plane including the X and Y directions. In the following description, “thickness” generally means the length in the Z direction. Also, in the following description, “plan view” generally means a plan view viewed from the X-Y plane.

The semiconductor device PKG1 of this embodiment includes a wiring substrate SUB1 (see FIG. 1), a semiconductor component SC1 (see FIG. 2), a semiconductor component SC2 (see FIG. 2), and a lid (metal plate) L1 (see FIG. 1).

As shown in FIG. 3, the wiring substrate SUB1 has an upper surface (surface, main surface, component mounting surface) 2t, which is the mounting surface for semiconductor components. The wiring substrate SUB1 also has a lower surface (surface, main surface, mounting surface) 2b on the opposite side of the upper surface 2t. The upper surface 2t and the lower surface 2b of the wiring substrate SUB1 are, for example, rectangular. As shown in FIGS. 1 and 2, in plan view, the wiring substrate SUB1 has four sides 2s.

The semiconductor component SC1 includes a lower surface 3b facing the upper surface 2t of the wiring substrate SUB1 and an upper surface 3t on the opposite side of the lower surface 3b. As shown in FIG. 2, the semiconductor component SC1 is mounted on the region R1 of the upper surface 2t of the wiring substrate SUB1.

As shown in FIG. 3, the semiconductor component SC2 includes a lower surface 4b facing the upper surface 2t of the wiring substrate SUB1 and an upper surface 4t on the opposite side of the lower surface 4b. As shown in FIG. 2, the semiconductor component SC2 is mounted on region R2 of the upper surface 2t of the wiring substrate SUB1.

The lid L1 includes a lower surface 5b facing the upper surface 3t of the semiconductor component SC1 and the upper surface 4t of the semiconductor component SC2, and an upper surface 5t opposite the lower surface 5b. The lid L1 is arranged on the wiring substrate SUB1.

The semiconductor device PKG1 also includes an adhesive layer BND1 and an adhesive layer BND2. The adhesive layer BND1 is arranged between the upper surface 3t of the semiconductor component SC1 and the lower surface 5b of the lid L1. The adhesive layer BND2 is arranged between the upper surface 4t of the semiconductor component SC2 and the lower surface 5b of the lid L1.

As shown in FIG. 3, the wiring substrate SUB1 includes terminals (terminal 2PD) on the upper surface 2t side, which is the component mounting surface, and terminals (land 2LD) on the lower surface 2b side, which is the mounting surface. The wiring substrate SUB1 includes multiple wiring layers WL1, WL2, WL3, WL4, WL5, WL6, WL7, and WL8 that electrically connect the terminal 2PD and the land 2LD. Each wiring layer is located between the upper surface 2t and the lower surface 2b. Each wiring layer has a conductor pattern such as wiring, which is a path for supplying signals and power. An insulating film 2e is arranged between each wiring layer. Each wiring layer is electrically connected to each other via a via wiring 2v, which is an interlayer conductive path penetrating through the insulating film 2e, or a through-hole wiring 2THW. In this embodiment, although a wiring substrate with eight wiring layers is exemplified as an example of the wiring substrate SUB1, the number of wiring layers provided in the wiring substrate SUB1 is not limited to eight layers. For example, a wiring substrate with seven or fewer layers or nine or more layers can be used as a modified example.

Among the multiple wiring layers, the wiring layer WL1, which is arranged closest to the upper surface 2t side, is covered with an insulating film SR1. The insulating film SR1 has an opening portion, and multiple terminals 2PD provided on the wiring layer WL1 are exposed from the insulating film SR1 at the opening portion. Among the multiple wiring layers, the wiring layer WL8, which is arranged closest to the lower surface 2b side of the wiring substrate SUB1, is provided with multiple lands, and the wiring layer WL8 is covered with an insulating film SR2. Each of the insulating films SR1 and SR2 is a solder resist film. Each of the multiple terminals 2PD provided on the wiring layer WL1 and the multiple lands 2LD provided on the wiring layer WL8 is electrically connected via the conductor pattern formed in each wiring layer provided in the wiring substrate SUB1. The above conductor pattern includes wiring 2d, large-area conductor patterns, the via wiring 2v, and the through-hole wiring 2THW.

The wiring substrate SUB1 is formed by laminating multiple wiring layers on the upper surface 2Ct and the lower surface 2Cb of an insulating layer 2CR made of, for example, prepreg. The wiring layer WL4 and the wiring layer WL5 are electrically connected via multiple through-hole wirings 2THW embedded in multiple through-holes, respectively, provided so as to penetrate from one of the upper surfaces 2Ct and the lower surface 2Cb to the other.

As a modified example of FIG. 3, there may be a case where a so-called coreless substrate is used, which is formed by sequentially laminating insulating films 2e and conductor patterns such as wiring 2d without having an insulating layer 2CR made of hard materials such as prepreg material. When a coreless substrate is used, the through-hole wiring 2THW is not formed, and each wiring layer is electrically connected via the via wiring 2v.

In the example shown in FIG. 3, each of the multiple lands 2LD is connected with a solder ball (solder material, external terminal, electrode, external electrode) SB. The solder ball SB is a conductive member for electrically connecting the multiple lands 2LD with multiple terminals (not shown) on the motherboard side when mounting the semiconductor device PKG1 on a motherboard (not shown).

As mentioned above, semiconductor components SC1 and SC2 are mounted on the upper surface 2t of the wiring substrate SUB1. As shown in FIG. 2, in plan view, semiconductor components SC1 and SC2 do not overlap and are mounted in different regions of the upper surface 2t.

In the case of the present embodiment, the semiconductor component SC1 is a semiconductor chip. Specifically, it is a System on Chip (SoC) where computational circuits and memory circuits electrically connected to each other are mounted on a single chip.

Also, in the case of the present embodiment, the semiconductor component SC2 is a semiconductor package. Specifically, it includes a semiconductor chip 41 (see FIG. 3) where memory circuits are formed, an interposer substrate 42 (see FIG. 3) on which the semiconductor chip 41 is mounted, and a sealing body 43 (see FIG. 3) that seals the semiconductor chip 41. A semiconductor chip mainly formed with memory circuits like semiconductor chip 41 is called a memory chip. Similarly, a semiconductor package mainly equipped with memory chips like semiconductor component SC1 is called a memory package.

The semiconductor component SC1 and the semiconductor component SC2 are electrically connected to each other via the wiring substrate SUB1.

As shown in FIG. 3, the semiconductor component SC1 includes an upper surface (surface, main surface) 3t and a lower surface (surface, main surface) 3b opposite to the upper surface 3t. As shown in FIG. 2, in plan view, the semiconductor component SC1 has four sides 3s. The planar shape of the semiconductor component SC1 forms a quadrilateral. In the example shown in FIG. 2, one of the four sides 3s of the semiconductor component SC1 extends along one of the four sides 2s of the wiring substrate SUB1.

On the lower surface 3b of the semiconductor component SC1, multiple electrodes (pads, electrode pads, bonding pads) 3PD are arranged. In the example shown in FIG. 3, the semiconductor component SC1 is mounted on the wiring substrate SUB1 with the lower surface 3b, which is the electrode formation surface, facing the upper surface 2t of the wiring substrate SUB1. This mounting method is called face-down mounting or flip-chip connection method.

Although not shown, the main surface of the semiconductor component SC1 (specifically, the semiconductor element formation region provided on the element formation surface of the semiconductor substrate, which is the base material of the semiconductor component SC1) has multiple semiconductor elements (circuit elements) formed. The multiple electrodes 3PD are electrically connected to these multiple semiconductor elements via a wiring (not shown) formed in the wiring layer arranged inside the semiconductor component SC1.

The semiconductor component SC1 (specifically, the semiconductor substrate, which is the base material of semiconductor component SC1) is made of silicon (Si), for example. Also, an insulating film covering the base material and wiring of the semiconductor component SC1 is formed on the lower surface 3b, and a part of each of the multiple electrodes 3PD is exposed from the insulating film at the opening portion formed in the insulating film.

As shown in FIG. 3, each of the multiple electrodes 3PD is connected to a protruding electrode 3BP. The multiple electrodes 3PD of the semiconductor component SC1 and the multiple terminals 2PD of the wiring substrate SUB1 are electrically connected via multiple protruding electrodes 3BP. The protruding electrode (bump electrode) 3BP is a metal member (conductive member) formed to protrude on the lower surface 3b of the semiconductor component SC1.

Also, as shown in FIG. 3, an underfill resin (insulating resin) UF1 is arranged between the semiconductor component SC1 and the wiring substrate SUB1. The underfill resin UF1 is arranged to fill the space between the lower surface 3b of the semiconductor component SC1 and the upper surface 2t of the wiring substrate SUB1. Each of the multiple protruding electrodes 3BP is sealed by the underfill resin UF1.

As shown in FIG. 3, the semiconductor component SC2 includes an upper surface (surface, main surface) 4t and a lower surface (surface, main surface) 4b opposite to the upper surface 4t. As shown in FIG. 2, in plan view, the semiconductor component SC2 has four sides 4s. The planar shape of the semiconductor component SC1 forms a quadrilateral. In the example shown in FIG. 2, one of the four sides 4s of the semiconductor component SC2 extends along one of the four sides 2s of the wiring substrate SUB1. Also, in plan view, another one of the four sides 4s of the semiconductor component SC2 faces one of the four sides 3s of the semiconductor component SC1.

On the lower surface 4b of the semiconductor component SC2, multiple lands (electrodes, pads, bonding pads) 4PD are arranged. In the example shown in FIG. 3, the semiconductor component SC1 is mounted on the wiring substrate SUB1 with the lower surface 4b, which is the external terminal formation surface, facing the upper surface 2t of the wiring substrate SUB1.

Although not shown, the interposer substrate 42 is equipped with multiple wirings, and the semiconductor chip 41 is electrically connected to the multiple lands 4PD via these wirings.

As shown in FIG. 3, each of the multiple lands 4PD is connected to a protruding electrode 4BP. The multiple lands 4PD of the semiconductor component SC2 and the multiple terminals 2PD of the wiring substrate SUB1 are electrically connected via multiple protruding electrodes 4BP. The protruding electrode (bump electrode) 4BP is a metal member (conductive member) formed to protrude on the lower surface 4b of the semiconductor component SC1.

The underfill resin (insulating resin) UF2 is arranged between the semiconductor component SC2 and the wiring substrate SUB1. The underfill resin UF2 is arranged to fill the space between the lower surface 4b of the semiconductor component SC1 and the upper surface 2t of the wiring substrate SUB1. Each of the multiple protruding electrodes 4BP is sealed by the underfill resin UF2.

Each of the semiconductor component SC1 and the semiconductor component SC2 is covered by a lid L1. Lid L1 includes a lower surface 5b facing the upper surface 3t of the semiconductor component SC1 or the upper surface 4t of the semiconductor component SC2, and an upper surface 5t opposite to the lower surface 5b.

The lid L1 functions as a heat dissipation path to suppress the temperature rise of the semiconductor component SC1 and the semiconductor component SC2. The lid L1 is a metal plate made of metal with high thermal conductivity. The lid L1 is made of, for example, copper. The thermal conductivity of lid L1 is higher than the thermal conductivity of the semiconductor substrate equipped in the semiconductor component SC1, for example. As a method of dissipating heat through the lid L1, besides dissipating heat externally from the lid L1 itself, the heat dissipation fin (heat dissipation member) RDF may be attached onto the lid L1 as shown in FIG. 4.

The semiconductor device PKG2 shown in FIG. 4 further includes the heat dissipation fin RDF having a lower surface 6b facing the upper surface 5t of lid L1. Also, the semiconductor device PKG2 further includes an adhesive layer BND4 adhered to each of the upper surface 5t of lid L1 and the lower surface 6b of heat dissipation fin RDF. The heat generated in the semiconductor component SC1 and the heat generated in the semiconductor component SC2 are mainly released externally through the lid L1, the adhesive layer BND4, and the heat dissipation fin RDF.

As shown in FIG. 1, lid L1 includes a flange portion LFP, a cover portion LCP, and a support portion LSP. The flange portion LFP is adhered to the upper surface 2t of the wiring substrate SUB1 via the adhesive layer BND3 (see FIG. 3). The cover portion LCP is located above the semiconductor component SC1 and the semiconductor component SC2. The support portion LSP connects the flange portion LFP and the cover portion LCP. The support portion LSP is a member for supporting the cover portion LCP arranged at a position which is higher than the flange portion LFP.

To efficiently function lid L1 as a heat dissipation path, it is necessary to thermally connect each of the semiconductor component SC1 and the semiconductor component SC2 with the lid L1. Each of the semiconductor component SC1 and the semiconductor component SC2 is fixed to the lid L1 via an adhesive layer.

Specifically, the semiconductor component SC1 is fixed to the lid L1 via the adhesive layer BND1. The adhesive layer BND1 is arranged between the upper surface 3t of the semiconductor component SC1 and the lower surface 5b of the lid L1. The semiconductor component SC2 is fixed to the lid L1 via the adhesive layer BND2. The adhesive layer BND2 is arranged between the upper surface 3t of the semiconductor component SC2 and the lower surface 5b of the lid L1.

Each of the adhesive layer BND1 and the adhesive layer BND2 not only functions to fix the semiconductor component SC1 and the semiconductor component SC2 to the lid L1 but also serves as a part of the heat dissipation path. Therefore, it is preferable that each of the adhesive layer BND1 and the adhesive layer BND2 has the high thermal conductivity.

From the above perspective, a preferred material for the adhesive layers BND1 and BND2 can be exemplified by using a conductive paste that mixes metal particles such as silver filler in a resin paste. However, the thermal conductivity of each adhesive layer BND1 and BND2 is lower than the thermal conductivity of the lid L1.

### Heat Dissipation Characteristics

Next, the heat dissipation characteristics in the heat dissipation path including the lid L1 will be examined. As shown in FIG. 3, in the case of the present embodiment, multiple semiconductor components (semiconductor component SC1 and semiconductor component SC2) are connected to a single lid L1. In this case, if the heights of the upper surfaces of the multiple semiconductor components differ from each other, the heat dissipation characteristics in some heat dissipation paths may be inferior compared to others due to this height difference.

For example, in the case of the present embodiment, as shown in FIG. 3, when the upper surface 2t of the wiring substrate SUB1 is used as a reference plane, the height of the upper surface 3t of the semiconductor component SC1 (i.e., the mounting height of the semiconductor component SC1) is lower than the height of the upper surface 4t of the semiconductor component SC2 (i.e., the mounting height of the semiconductor component SC2).

Although not shown, as an examined example for the present embodiment, consider the case where the lower surface 5b (see FIG. 3) of the cover portion LCP (see FIG. 1) is a flat surface. In this examined example, the short distance from the upper surface 3t of the semiconductor component SC1 to the lid L1 is longer than the shortest distance from the upper surface 4t of the semiconductor component SC2 to the lid L1. Therefore, the thickness of the adhesive layer BND1 is larger than the thickness of the adhesive layer BND2. In this case, the heat dissipation path via the adhesive layer BND1 has lower thermal conduction efficiency compared to the heat dissipation path via the adhesive layer BND2. In other words, the heat dissipation characteristics of the heat dissipation path connected to the semiconductor component SC1 are inferior to the heat dissipation characteristics of the heat dissipation path connected to the semiconductor component SC2.

In the case of the present embodiment, the heat generation amount of the semiconductor component SC1, which is an SoC, is greater than the heat generation amount of the semiconductor component SC2, which is a memory package. In this case, it is particularly important to improve the heat dissipation characteristics in the heat dissipation path connected to the semiconductor component SC1. This is to prevent the circuit provided in the semiconductor component SC1 from malfunctioning due to temperature rise or the operation speed of the above circuit from decreasing.

From the perspective of improving the heat dissipation efficiency in the heat dissipation path via the adhesive layer BND1, it is preferable that the thickness of the adhesive layer BND1 is thin. Therefore, in the present embodiment, as shown in FIG. 3, the lid L1 is provided with the following structure to bring the distance between the upper surface 3t of the semiconductor component SC1 and the lower surface 5b of the lid L1 closer.

That is, as shown in FIG. 1, the cover portion LCP of the lid L1 includes a portion 5CV. As shown in FIG. 3, the portion 5CV forms a shape protruding in the direction toward the semiconductor component SC1 at a position facing the upper surface 3t of the semiconductor component SC1.

As shown in FIG. 4, when the upper surface 2t of the wiring substrate SUB1 is used as a reference plane, the lower surface 5CVb of the portion 5CV is at a lower position than the region other than the portion 5CV of the lower surface 5b of the cover portion LCP. Therefore, compared to the examined example where the lower surface 5b of the cover portion LCP is a flat surface, the shortest distance between the lid L1 and the semiconductor component SC1 can be reduced. In other words, the thickness of the adhesive layer BND1 can be made thinner. For example, in the example shown in FIG. 4, the thickness of the adhesive layer BND1 is about 50 μm to 100 μm. Also, the thickness of the adhesive layer BND2 is about 50 μm to 100 μm.

By reducing the thickness of the adhesive layer BND1, the heat dissipation efficiency in the heat dissipation path via the adhesive layer BND1 is improved.

Meanwhile, from the perspective of reducing the thickness of the adhesive layer BND1, it is sufficient if the shape of the portion 5CV simply protrudes toward the semiconductor component SC1. In other words, even if the shape of the upper surface 5t of the cover portion LCP is flat, if the position of the lower surface 5CVb can be brought closer to the semiconductor component SC1, the thickness of the adhesive layer BND1 can be reduced.

However, in the case of the present embodiment, the lid L1 is formed by applying drawing processing (plastic deformation processing using press processing) to a flat metal plate. Therefore, the thickness of portion 5CV and the thickness of the parts other than the portion are the same. Note that due to the precision of machining, there may be a slight difference between the thickness of the portion 5CV and the thickness of the parts other than the portion 5CV. The term “same” mentioned in this paragraph means that even if a slight difference occurs as described above, it is considered substantially the same to the extent that the difference is negligible.

When forming the lid L1 by drawing processing, the portion 5CV, the cover portion LCP, the flange part LFP (see FIG. 1), and the support part LSP (see FIG. 1) can be formed collectively. That is, compared to the case of forming a protruding part on a flat cover portion LCP as the portion 5CV, it can be manufactured easily.

Also, as a method of forming a protruding part on a flat cover portion LCP, a method of removing part of the metal plate by etching can be considered. In this case, it is necessary to prepare a metal plate thicker than the metal plate used as the lid L1. On the other hand, when forming the lid L1 by drawing processing, it is sufficient to prepare a metal plate with the same thickness as the metal plate used as the lid L1, thereby reducing material costs.

For the above reasons, in the present embodiment, a lid L1 formed by drawing processing is used. When the portion 5CV is formed by drawing processing, a protruding portion is formed on the lower surface 5b of the cover portion LCP (see FIG. 3), and a recess portion CCP (see FIG. 1) is formed on the upper surface 5t.

As shown in FIG. 1, the upper surface 5t of the cover portion LCP includes a bottom surface 5tb, an upper surface 5tt, and a side surface 5ts. As shown in FIG. 3, the bottom surface 5tb is part of the portion 5CV and is arranged in a region overlapping with the semiconductor component SC1. The upper surface 5tt includes a region overlapping the semiconductor component SC2, and the upper surface 5tt is arranged at a position which is higher than the bottom surface 5tb when the upper surface 2t of the wiring substrate SUB1 is used as a reference plane in cross-sectional view. The side surface 5ts shown in FIG. 1 is connecting the bottom surface 5tb and the upper surface 5tt. Note that the side surface 5ts of the present embodiment is inclined with respect to the bottom surface 5tb or the upper surface 5tt, as shown in FIG. 3.

Meanwhile, as mentioned above, the semiconductor device PKG2 shown in FIG. 4 is further equipped with a heat dissipation fin RDF mounted via an adhesive layer BND4 on the lid L1. The adhesive layer BND4 is adhered to each of the bottom surface 5tb, the side surface 5ts, and the upper surface 5tt. In the case of the semiconductor device PKG2, the thickness of the adhesive layer BND4 arranged on the bottom surface 5tb is larger than the thickness of the adhesive layer BND4 arranged on the upper surface 5tt. In other words, the thickness of the portion of the adhesive layer BND4 arranged on the bottom surface 5tb is larger than the thickness of the portion arranged on the upper surface 5tt. In this case, the heat dissipation efficiency of the adhesive layer BND4 arranged on the bottom surface 5tb is inferior to the heat dissipation efficiency of the adhesive layer BND4 arranged on the upper surface 5tt.

However, the lid L1 is an integral object including the bottom surface 5tb and the upper surface 5tt. In this case, part of the heat generated from the semiconductor component SC1 is transmitted to the heat dissipation fin RDF via the upper surface 5tt of the lid L1.

Therefore, considering the heat dissipation path transmitted to the heat dissipation fin RDF via the portion 5CV of the lid L1 and the upper surface 5tt of the lid L1 mentioned above, the decrease in heat dissipation characteristics due to the formation of the recess portion CCP (see FIG. 1) can be suppressed.

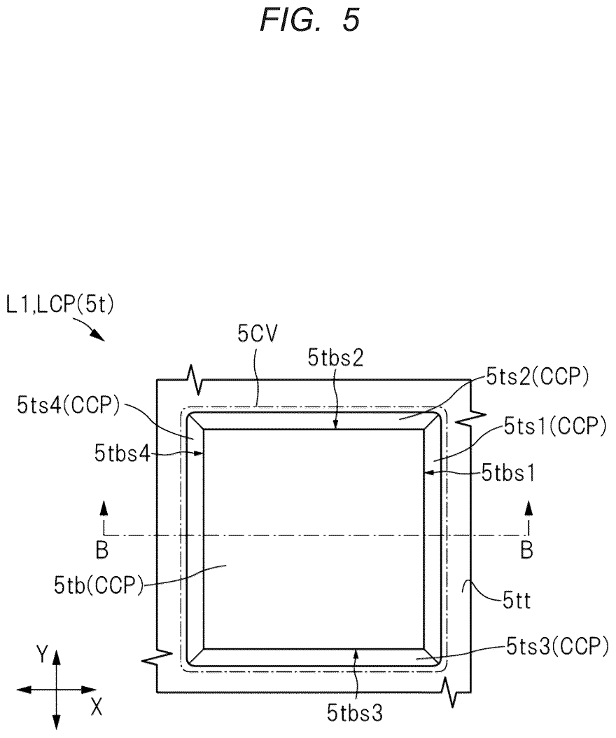

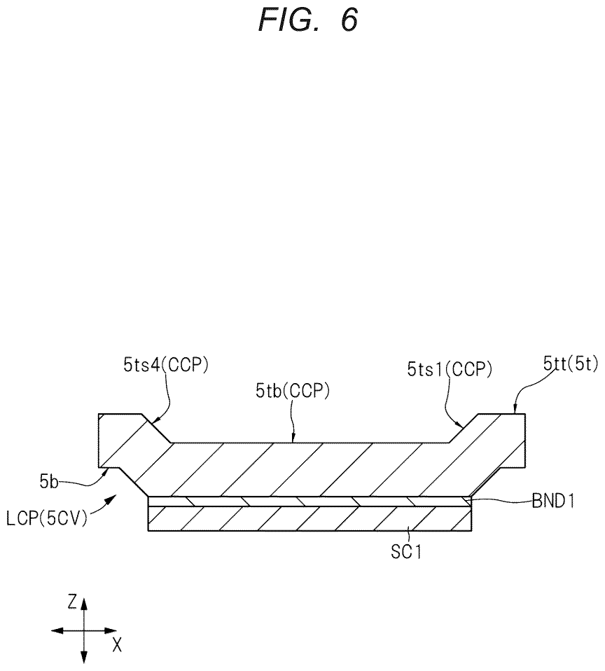

Next, the details of the recess provided in lid L1 of the present embodiment will be described using FIGS. 5 and 6. FIG. 5 is an enlarged plan view showing the periphery of the portion protruding toward the semiconductor component in the lid shown in FIG. 1. FIG. 6 is an enlarged cross-sectional view along line B-B of FIG. 5.

As shown in FIG. 5, in plan view, the bottom surface 5tb forms a quadrilateral. Specifically, the bottom surface 5tb includes a side 5tbs1 extending in the Y direction, a side 5tbs2 extending in the X direction, a side 5tbs3 opposite to the side 5tbs2, and a side 5tbs4 opposite to the side 5tbs1.

As shown in FIG. 5, the side surface 5ts (see FIG. 1) includes a side surface 5ts1 connected to the side 5tbs1, a side surface 5ts2 connected to the side 5tbs2, a side surface 5ts3 connected to the side 5tbs3, and a side surface 5ts4 connected to the side 5tbs4.

As shown in FIG. 1, the cover portion LCP of the lid L1 in the present embodiment forms a quadrilateral in plan view. Also, the flange part LFP of the lid L1 forms a frame shape arranged so as to surround the cover portion LCP. The portion 5CV is arranged inside the periphery of the cover portion LCP. In other words, the upper surface 5tt of the lid L1 (see FIG. 6) is interposed between the portion 5CV and the flange part LFP.

In the present embodiment, when a flange portion LFP in a frame shape is arranged around the cover portion LCP, the support strength of the heat dissipation fin RDF (see FIG. 4) by the lid L1 is higher compared to the semiconductor device PKG3 described later as a modified example.

### First Modified Example

Next, a modified example for the semiconductor device PKG1 (see FIGS. 1 to 4) and the semiconductor device PKG2 (see FIG. 4) described using FIGS. 1 to 6 will be explained.

In the case of the semiconductor device PKG2 shown in FIG. 4, as shown in FIG. 5, the periphery of the bottom surface 5tb is surrounded by side surfaces 5ts1, 5ts2, 5ts3, and 5ts4. Therefore, when mounting the heat dissipation fin RDF on the lid L1 via the adhesive layer BND4 as shown in FIG. 4, there is a possibility that bubbles (voids) may remain in the adhesive layer BND4 within the recess portion CCP (see FIG. 5).

If bubbles remain in the adhesive layer BND4, they expand as the temperature of the semiconductor device PKG2 rises. Conversely, when the temperature of the semiconductor device PKG2 decreases, the bubbles contract. Depending on the position of the bubbles in the adhesive layer BND4 and the degree of volume change, delamination may occur at the adhesive interface between the adhesive layer BND4 and the lid L1, or between the adhesive layer BND4 and the lower surface 6b of the heat dissipation fin RDF.

Therefore, when mounting the heat dissipation fin RDF on the lid L1 via the adhesive layer BND4, it is preferable to ensure that no bubbles remain in the adhesive layer BND4.

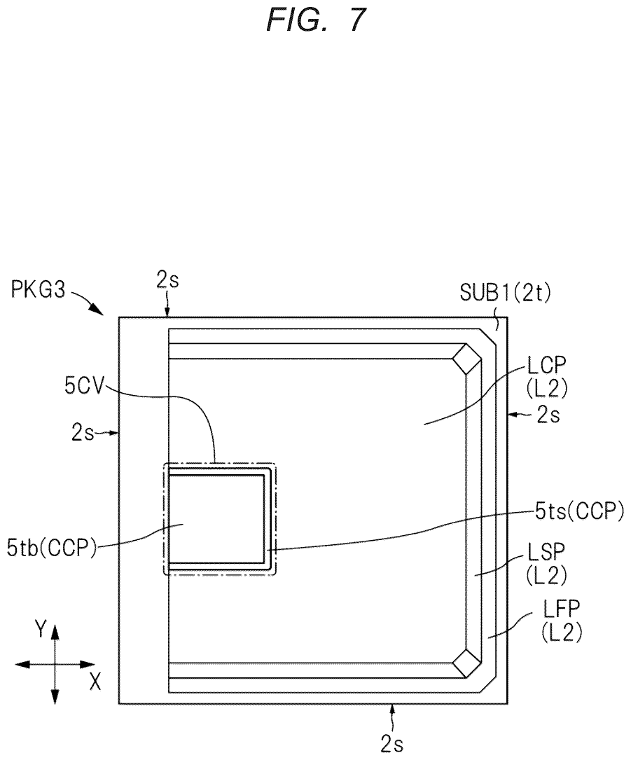

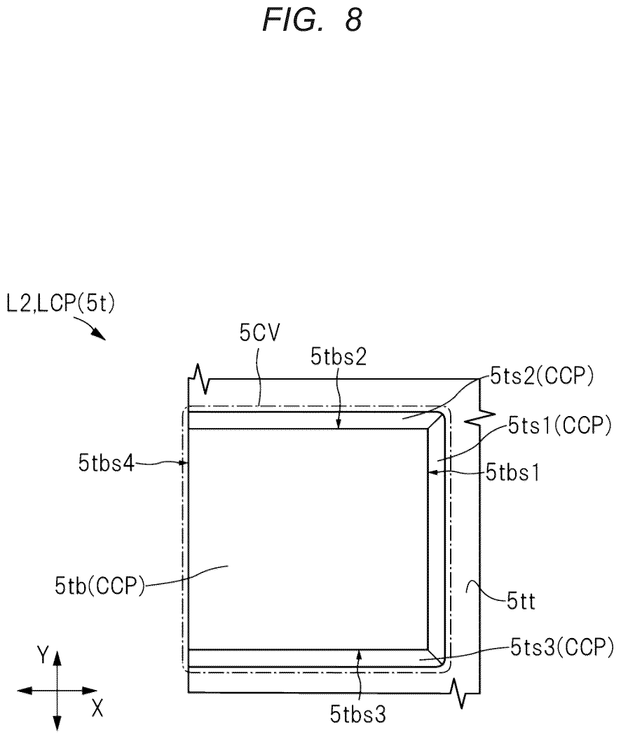

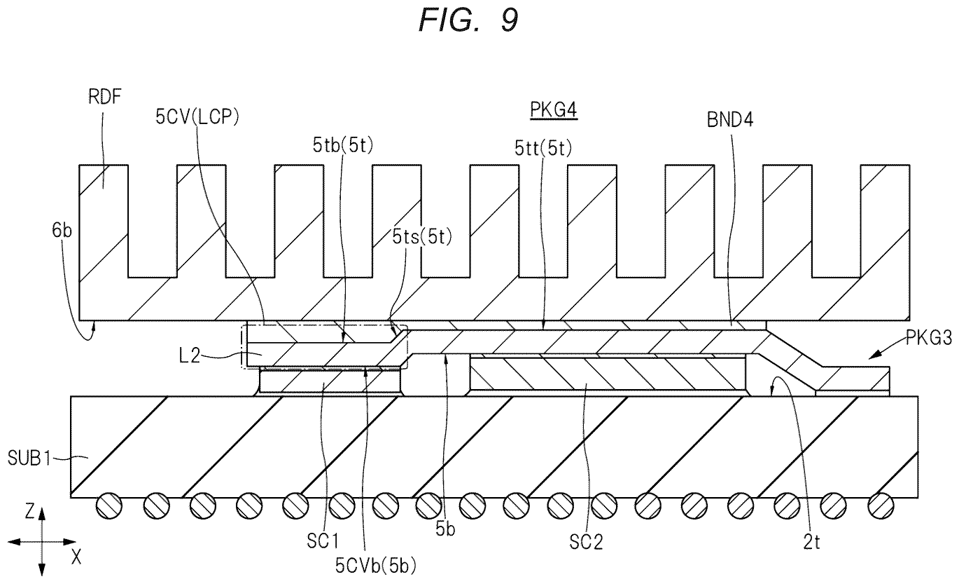

Below, a structure that can be manufactured to prevent bubbles from remaining in the adhesive layer BND4 will be described as a modified example of the above embodiment. FIG. 7 is a plan view of a semiconductor device that is a modified example of FIG. 1. FIG. 8 is an enlarged plan view of the periphery of the recess shown in FIG. 7. FIG. 9 is a cross-sectional view showing a state where the heat dissipation fin is mounted on the lid of the semiconductor device shown in FIG. 7.

The semiconductor device PKG3 shown in FIG. 7 differs in the shape of the lid L2 from the semiconductor device PKG1 shown in FIG. 1. Specifically, as shown in FIG. 8, the lid L2 does not have the side surface 5ts4 shown in FIG. 5. In other words, the bottom surface 5tb includes the side 5tbs4 that is not connected to the side surface 5ts (see FIG. 7), and the side 5tbs4 is included in the outer edge of the upper surface 5t of the lid L1.

In this modified example, the recess portion CCP of the lid L2 does not have the side surface 5ts4 (see FIG. 5). Therefore, the end portion, which includes the side 5tbs4, of the recess portion CCP of the lid L2 is an open end.

For example, the manufacturing method of the semiconductor device PKG4 shown in FIG. 9 includes a step of applying the adhesive layer BND4 on the lid L2, followed by a step of pressing the heat dissipation fin RDF onto the adhesive layer BND4 to adhere it. In this step of adhering the heat dissipation fin RDF, the bubbles in the adhesive layer BND4 can easily escape to the outside from the open end including the side 5tbs4 shown in FIG. 8.

In other words, the lid L2 of the semiconductor device PKG3 in this modified example has a structure that makes it difficult for bubbles to remain in the recess portion CCP compared to the lid L1 shown in FIG. 5.

Also, as shown in FIG. 7, the shape of the flange portion LFP of the lid L2 differs from that of the lid L1 shown in FIG. 1. That is, in the case of the lid L1 described using FIG. 1, the flange portion LFP forms a frame shape surrounding the cover portion LCP. On the other hand, the flange portion LFP of the lid L2 shown in FIG. 7 forms a C shape.

As shown in FIG. 9, the lid L2 has portions adhered to the semiconductor components SC1 and SC2, in addition to the flange portion LFP. Therefore, even if the flange portion LFP is C-shaped, a certain degree of strength can be ensured.

However, from the viewpoint of improving the support strength of the heat dissipation fin RDF (see FIG. 9), the semiconductor device PKG2 shown in FIG. 4 is preferable compared to this modified example.

Each of the semiconductor devices PKG3 and PKG4 described in this modified example is similar to the semiconductor devices PKG1 and PKG2 described using FIGS. 1 to 6, except for the differences mentioned above.

For example, as shown in FIG. 8, the bottom surface 5tb of the lid L2 forms a quadrilateral in plan view. Also, the side surfaces 5ts (see FIG. 7) include the side surface 5ts1 connected to the edge 5tbs1 of the bottom surface 5tb, the side surface 5ts2 connected to the edge 5tbs2 of the bottom surface 5tb, and the side surface 5ts3 connected to the edge 5tbs3 of the bottom surface 5tb. These points are similar to the lid L1 described using FIG. 5. Therefore, overlapping descriptions are omitted.

### Second Modified Example

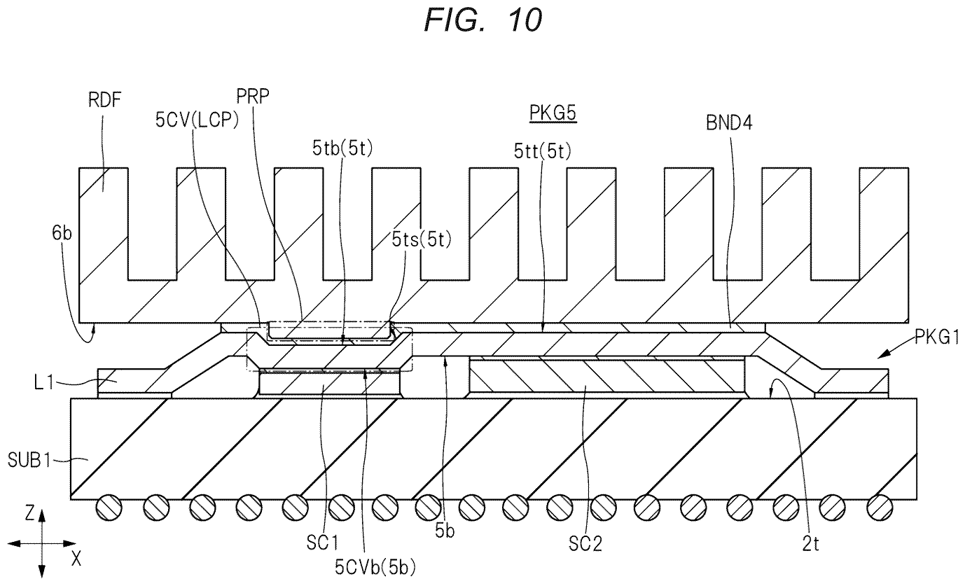

Next, another modified example for the semiconductor device PKG2 described using FIG. 4 will be explained. FIG. 10 is a cross-sectional view showing another modified example of FIG. 4. The semiconductor device PKG5 of this modified example includes the semiconductor device PKG1 described using FIGS. 1 to 6. Therefore, the description of the semiconductor device PKG1 is omitted, and each figure from FIGS. 1 to 6 is referenced and explained as necessary.

The semiconductor device PKG5 shown in FIG. 10 differs in the shape of the heat dissipation fin RDF from the semiconductor device PKG2 shown in FIG. 4. In the case of the semiconductor device PKG5 shown in FIG. 10, the heat dissipation fin RDF includes a protruding portion PRP that forms a shape protruding in the direction toward the lid L1 at a position facing the bottom surface 5tb of the lid L1. A part of the protruding portion PRP is arranged within the recess portion CCP (see FIG. 5) formed by the bottom surface 5tb, side surfaces 5ts1, 5ts2,5ts3, and 5ts4.

For example, the manufacturing method of the semiconductor device PKG5 shown in FIG. 10 includes a step of applying the adhesive layer BND4 on the lid L2, followed by a step of pressing the heat dissipation fin RDF onto the adhesive layer BND4 to adhere it.

In the step of adhering the heat dissipation fin RDF, the protruding portion PRP formed on the lower surface 6b of the heat dissipation fin RDF is inserted into the recess portion CCP (see FIG. 5) of the upper surface 5t of the lid L1. When the protruding portion PRP is inserted into the adhesive layer BND4, the adhesive layer BND4 is pressurized, making it easier for the bubbles in the adhesive layer BND4 to be discharged to the outside due to the pressure.

Therefore, the semiconductor device PKG5 shown in FIG. 10 has a structure that makes it easier to suppress the retention of bubbles between the heat dissipation fin RDF and the lid L1 compared to the semiconductor device PKG2 shown in FIG. 4.

Also, in this modified example, the semiconductor device PKG1 that supports the heat dissipation fin RDF has the same structure as the semiconductor device PKG1 shown in FIG. 4. Therefore, from the viewpoint of improving the support strength of the heat dissipation fin RDF, the semiconductor device PKG5 shown in FIG. 10 is preferable to the semiconductor device PKG4 shown in FIG. 9.

In this modified example, as shown in FIG. 10, a protrusion PRP is provided on the portion 5CV of the lid L1. For instance, the shortest distance from the bottom surface 5tb of the recess portion CCP (see FIG. 5) to the protrusion PRP is the same (or approximately the same) as the shortest distance from the upper surface 5tt of the lid L1 to the lower surface 6b of the heat dissipation fin RDF. For example, in the example shown in FIG. 10, the thickness of the adhesive layer BND4 arranged between the bottom surface 5tb and the protrusion PRP is approximately 50 μm to 100 μm. Similarly, the thickness of the adhesive layer BND4 arranged between the upper surface 5tt of the lid L1 and the heat dissipation fin RDF is also approximately 50 μm to 100 μm.

In this case, among the heat dissipation paths for the heat generated by the semiconductor component SC1, it is possible to improve the heat dissipation characteristics of the heat dissipation path that passes through the portion 5CV of the lid L1, the adhesive layer BND4, and the protrusion PRP.

Although the invention made by the present inventor has been specifically described based on the embodiment, the present invention is not limited to the above embodiment, and needless to say that various modifications can be made without departing from the gist thereof.

For example, each of the semiconductor devices PKG1 to PKG5 mentioned above are equipped with two semiconductor components. However, the number of semiconductor components is not limited to two, and there may be cases where three or more semiconductor components are provided.

Furthermore, for example, there may be cases where multiple modified examples mentioned above are combined with each other.

What is claimed is:

1. A semiconductor device comprising:
a wiring substrate having a first surface;
a first semiconductor component having: a second surface facing the first surface of the wiring substrate; and a third surface opposite the second surface, the first semiconductor component being mounted on a first region of the wiring substrate;
a second semiconductor component having: a fourth surface facing the first surface of the wiring substrate; and a fifth surface opposite the fourth surface, the second semiconductor component being mounted on a second region of the wiring substrate;
a metal plate having: a sixth surface facing the third surface of the first semiconductor component and the fifth surface of the second semiconductor component; and a seventh surface opposite the sixth surface, the metal plate being arranged on the wiring substrate;
a first adhesive layer arranged between the third surface of the first semiconductor component and the sixth surface of the metal plate; and
a second adhesive layer arranged between the fifth surface of the second semiconductor component and the sixth surface of the metal plate,
wherein, when the first surface of the wiring substrate is used as a reference plane in cross-sectional view, a height of the third surface of the first semiconductor component is lower than a height of the fifth surface of the second semiconductor component,
wherein the metal plate includes:
a flange portion adhered to the first surface of the wiring substrate via a third adhesive layer;
a cover portion located above the first semiconductor component and the second semiconductor component; and
a support portion connecting the flange portion and the cover portion,
wherein the cover portion of the metal plate includes a first portion that forms a shape protruding in a direction toward the first semiconductor component at a position facing the third surface of the first semiconductor component in cross-sectional view, and
wherein the seventh surface of the cover portion includes:
a bottom surface that is a part of the first portion and that is arranged in a region overlapping the first semiconductor component,
an eighth surface that includes a region overlapping the second semiconductor component and that is arranged at a position which is higher than the bottom surface when the first surface of the wiring substrate is used as the reference plane in cross-sectional view; and
a side surface connecting the bottom surface and the eighth surface.

2. The semiconductor device according to claim 1,
wherein, in plan view, the bottom surface forms a quadrilateral, and
wherein the side surface includes: a first side surface connected to a first side of the bottom surface; a second side surface connected to a second side of the bottom surface; and a third side surface connected to a third side of the bottom surface.

3. The semiconductor device according to claim 2,
wherein the side surface further includes a fourth side surface connected to a fourth side of the bottom surface, and
wherein, in plan view, the cover portion forms a quadrilateral, and the flange portion forms a frame shape arranged so as to surround the cover portion.

4. The semiconductor device according to claim 3, further comprising:
a heat dissipation member having a ninth surface facing the seventh surface of the metal plate; and
a fourth adhesive layer adhered to each of the seventh surface of the metal plate and the ninth surface of the heat dissipation member,
wherein the fourth adhesive layer is adhered to each of the bottom surface, the side surface and the eighth surface.

5. The semiconductor device according to claim 4,
wherein the heat dissipation member includes a protruding portion forming a shape protruding in a direction toward the metal plate at a position facing the bottom surface of the metal plate, and
wherein a part of the protruding portion is arranged within a recess portion formed by the bottom surface, the first side surface, the second side surface, the third side surface and the fourth side surface.

6. The semiconductor device according to claim 2,
wherein the bottom surface includes a fourth side that is not connected to the side surface, and
wherein the fourth side is included in an outer edge of the seventh surface of the metal plate.

7. The semiconductor device according to claim 1, further comprising:
a heat dissipation member having a ninth surface facing the seventh surface of the metal plate; and
a fourth adhesive layer adhered to each of the seventh surface of the metal plate and the ninth surface of the heat dissipation member,
wherein the fourth adhesive layer is adhered to each of the bottom surface, the side surface and the eighth surface, and
wherein a thickness of a portion of the fourth adhesive layer arranged on the bottom surface is larger than a thickness of a portion arranged on the eighth surface.

8. The semiconductor device according to claim 1,
wherein the first semiconductor component is a semiconductor chip,
wherein the second semiconductor component is a semiconductor package including a memory circuit, and
wherein the first semiconductor component and the second semiconductor component are electrically connected to each other via the wiring substrate.
